(19) United States
(12) Patent Application Publication
(10) Pub. No.: US 2026/0173393 A1
(43) Pub. Date: Jun. 18, 2026

(54) SEMICONDUCTOR DEVICE, MEMORY DEVICE, AND METHOD OF MANUFACTURING THE SEMICONDUCTOR DEVICE

(71) Applicant: Samsung Electronics Co., Ltd., Suwon-si (KR)

(72) Inventors: Yoonsang PARK, Suwon-si (KR); Kihong KIM, Suwon-si (KR); Sijung YOO, Suwon-si (KR); Dukhyun CHOE, Suwon-si (KR)

(73) Assignee: Samsung Electronics Co., Ltd., Suwon-si (KR)

(21) Appl. No.: 19/268,479

(22) Filed: Jul. 14, 2025

(30) Foreign Application Priority Data
Dec. 13, 2024 (KR) 10-2024-0186165

(51) Int. Cl. H10B 51/30; H10B 51/10; H10B 51/20

(52) U.S. Cl. CPC H10B 51/30; H10B 51/10; H10B 51/20

(57) ABSTRACT

A semiconductor device may include a channel layer, a ferroelectric layer on the channel layer, and a gate electrode on the ferroelectric layer. The ferroelectric layer may include a crystalline material, a first layer including zirconium oxide, a second layer including hafnium oxide, and a third layer including hafnium zirconium oxide. The first layer, the second layer, and the third layer may be sequentially stacked.

### CROSS-REFERENCE TO RELATED APPLICATION

This application is based on and claims priority under 35 U.S.C. § 119 to Korean Patent Application No. 10-2024-0186165, filed on Dec. 13, 2024, in the Korean Intellectual Property Office, the disclosure of which is incorporated by reference herein in its entirety.

### BACKGROUND

### 1. Field

The disclosure relates to a semiconductor device, a memory device, and/or a method of manufacturing the semiconductor device.

### 2. Description of the Related Art

Ferroelectrics are materials that possess ferroelectricity, which means that their internal electric dipole moments align to maintain spontaneous polarization even when no electric field is applied from the outside.

Recently, ferroelectricity has been found in semiconductor process-friendly HfO₂ and attempts to apply such HfO₂ to several devices continue. Among them, FeNAND, in which ferroelectrics are applied to NAND devices, is in the spotlight, and related research is actively underway. Like other NAND devices, FeNAND also may include multi-level operations, such as in a triple level cell (TLC) and a quad level cell (QLC) when operating the devices.

Also, ferroelectrics may be applied to a dynamic random access memory (DRAM) device. For example, DRAM devices may be implemented only with transistors without capacitors by using the spontaneous polarization characteristics of ferroelectrics.

### SUMMARY

Provided are a semiconductor device with an enlarged memory window, a memory device, and/or a method of manufacturing the semiconductor device.

Additional aspects will be set forth in part in the description which follows and, in part, will be apparent from the description, or may be learned by practice of the presented embodiments of the disclosure.

According to an aspect of an embodiment, a semiconductor device may include a channel layer, a ferroelectric layer on the channel layer, and a gate electrode on the ferroelectric layer. The ferroelectric layer may include a crystalline material. The ferroelectric layer may include a first layer including zirconium oxide, a second layer including hafnium oxide, and a third layer including hafnium zirconium oxide. The first layer, the second layer, and the third layer may be sequentially stacked.

In some embodiments, a crystalline direction of the first layer, a crystalline direction of the second layer, and a crystalline direction of the third layer may be aligned in a same direction.

In some embodiments, a crystalline direction of the ferroelectric layer may be aligned in a direction (001).

In some embodiments, the ferroelectric layer may have peaks at 6±1° and 12±1° as a result of in-plane XRD analysis.

In some embodiments, the ferroelectric layer may include a plurality of crystalline phases and an amorphous phase between the plurality of crystalline phases.

In some embodiments, the ferroelectric layer comprises the plurality of crystalline phases and the amorphous phase in a volume ratio (vol %) of 20:80 to 80:20.

In some embodiments, the amorphous phase may include substantially a same material as the material of the first layer, the second layer, and the third layer.

In some embodiments, the amorphous phase may include a first amorphous layer including zirconium oxide, a second amorphous layer including hafnium oxide, and a third amorphous layer including hafnium zirconium oxide.

In some embodiments, the amorphous phase may include a low-k dielectric material.

In some embodiments, the semiconductor device may further include a first interfacial layer on the channel layer.

In some embodiments, the semiconductor device may further include a second interface layer between the ferroelectric layer and the gate electrode.

In some embodiments, the semiconductor device may further include a charge trap layer on the ferroelectric layer.

In some embodiments, a thickness of the first layer may be in a range of 5 Å to 20 Å.

In some embodiments, a thickness of the third layer may be larger than a thickness of the second layer, and the thickness of the third layer may be larger than a thickness of the first layer.

In some embodiments, the thickness of the first layer may be greater than that of the second layer.

In some embodiments, the thickness of the second layer may be in a range of 0 Å to 15 Å.

In some embodiments, the thickness of the third layer may be in a range of 20 Å to 100 Å.

In some embodiments, the semiconductor device may further include a low-k material layer. The ferroelectric layer may include a first ferroelectric layer and a second ferroelectric layer spaced apart from the first ferroelectric layer. The low-k material layer may include a material having a dielectric constant less than a dielectric constant of the first ferroelectric layer and a dielectric constant of the second ferroelectric layer. The low-k material layer may be between the first ferroelectric layer and the second ferroelectric layer. The first ferroelectric layer and the second ferroelectric layer each may include the first layer including zirconium oxide, the second layer including hafnium oxide, and the third layer including hafnium zirconium oxide. In each of the first ferroelectric layer and the second ferroelectric layer, respectively, the first layer, the second layer, and the third layer may be sequentially stacked on the channel layer.

According to an embodiment, a memory device may include a plurality of memory cells spaced apart from each other vertically on a substrate. Each of the plurality of memory cells may include a gate electrode extending vertically on the substrate, a plurality of ferroelectric layers spaced apart from each other on the gate electrode, and a channel layer on the plurality of ferroelectric layers. The plurality of ferroelectric layers may include a crystalline material. The plurality of ferroelectric layers each may include a first layer including zirconium oxide, a second layer including hafnium oxide, and a third layer including hafnium zirconium oxide. The first layer, the second layer, and the third layer may be sequentially stacked on the channel layer.

According to an aspect of an embodiment, a method of manufacturing a semiconductor device may include forming a channel layer; forming a first precursor layer including zirconium oxide on the channel layer; forming a second precursor layer including hafnium oxide on the first precursor layer; annealing at least one of the first precursor layer and the second precursor layer; forming a third precursor layer including hafnium zirconium oxide on the second precursor layer after the annealing at least one of the first precursor layer and the second precursor layer; annealing the third precursor layer; and forming a gate electrode on the third precursor layer.

In some embodiments, the method may further include forming an etched region by selectively etching an uncrystallized portion of the first precursor layer, an uncrystallized portion of the second precursor layer, and an uncrystallized portion of the third precursor layer; and forming a low dielectric constant material layer in the etched region. The etched region may be an opening extending through a stack of a remaining portion of the first precursor layer, a remaining portion of the second precursor layer, and a remaining portion of the third precursor layer after the forming the etched region is performed.

In some embodiments, the method may further include selectively etching uncrystallized portions of the first precursor layer, the second precursor layer, and the third precursor layer, and forming a low dielectric constant material layer on the etched region.

In some embodiments, the etching may include selectively etching at least a portion of the uncrystallized portions of the first precursor layer, the second precursor layer, and the third precursor layer.

In some embodiments, the annealing of any one or more of the first precursor layer and the second precursor layer may be performed after the formation of the first precursor layer.

In some embodiments, the annealing of any one or more of the first precursor layer and the second precursor layer may be performed after the formation of the first precursor layer and the second precursor layer.

In some embodiments, the annealing of any one or more of the first precursor layer and the second precursor layer may be performed after the formation of the first precursor layer and may be performed again after the formation of the second precursor layer.

In some embodiments, the annealing of any one or more of the first precursor layer and the second precursor layer may be performed so as to crystallize at least a portion of the first precursor layer and the second precursor layer.

In some embodiments, the annealing of any one or more of the first precursor layer and the second precursor layer may be performed after depositing a metal on the first precursor layer.

In some embodiments, the annealing of any one or more of the first precursor layer and the second precursor layer may be performed under a temperature condition of 350° C. to 600° C.

In some embodiments, the annealing of the third precursor layer may be performed such that a portion of the third precursor layer is crystallized.

In some embodiments, the annealing of the third precursor layer may be performed such that the ferroelectric layer has an orthorhombic crystal structure.

In some embodiments, the annealing of the third precursor layer may be performed such that a crystalline direction of the ferroelectric layer is aligned in a direction (001).

In some embodiments, the annealing of the third precursor layer may be performed after depositing a metal on the third precursor layer.

In some embodiments, the annealing of the third precursor layer may be performed under a temperature condition of 350° C. to 600° C.

In some embodiments, the annealing of the third precursor layer may be performed for about 0.5 seconds or more, about 1 second or more, about 3 seconds or more, or about 5 seconds or more, and may be performed for about 1 minute or less, about 5 minutes or less, or about 10 minutes or less.

### BRIEF DESCRIPTION OF THE DRAWINGS

The above and other aspects, features and advantages of certain embodiments of the disclosure will be more apparent from the following description taken in conjunction with the accompanying drawings, in which:

FIG. 1 is a cross-sectional view illustrating a semiconductor device according to an embodiment;

FIG. 2 is a cross-sectional view illustrating a semiconductor device according to an embodiment;

FIG. 3 is a cross-sectional view illustrating a semiconductor device according to an embodiment;

FIG. 4 is a cross-sectional view illustrating a semiconductor device according to an embodiment;

FIGS. 5A to 5I are diagrams illustrating a method of manufacturing a semiconductor device according to an embodiment;

FIG. 6A shows in-plane X-ray diffraction (XRD) data of a ferroelectric layer of a semiconductor device according to an Example 1 and a Comparative Example 1;

FIGS. 6B to 6D are graphs illustrating a P-V curve of a semiconductor device according to a Comparative Example 2, an Example 2, and a Comparative Example 3;

FIG. 7 is a scanning electron microscope (SEM) image of a ferroelectric layer according to an Example 1;

FIGS. 8A and 8B are graphs showing a scanning electron microscope (SEM) image of a surface of a ferroelectric layer according to a Comparative Example and a P-V curve of a semiconductor device including a ferroelectric layer according to the Comparative Example;

FIG. 9 is a perspective view illustrating a memory device according to an embodiment;

FIG. 10 is a plan view of the memory device illustrated in FIG. 9;

FIG. 11 is a cross-sectional view taken along line I-I′ of FIG. 10;

FIG. 12 is a schematic block diagram of a display device including a display driver integrated circuit (DDI) including a semiconductor device and a display device including a DDI according to an embodiment;

FIG. 13 is a block diagram of an electronic system including a semiconductor device according to an embodiment; and

FIG. 14 is a block diagram of an electronic system including a semiconductor device according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, a semiconductor device and a method of manufacturing the semiconductor device according to various embodiments will be described in detail with reference to the accompanying drawings. In the following drawings, the same reference numerals refer to the same components and the size of each component in the drawings may be exaggerated for clarity and convenience of description. In addition, the embodiments described below are merely exemplary and various modifications are possible from these embodiments.

Hereinafter, the term “upper portion” or “on” may also include “to be present above on a non-contact basis” as well as “to be on the top portion in directly contact with”. The singular expression includes plural expressions unless the context clearly implies otherwise. In addition, when a part “includes” a component, this means that the part may further include other components, not excluding other components unless otherwise stated.

The use of the term “the” and similar indicative terms may correspond to both singular and plural. If there is no explicit description or contrary description of the order of the steps or operations constituting the method, these steps or operations may be carried out in an appropriate order and are not necessarily limited to the described order.

The connection or connection members of lines between the components shown in the drawings exemplarily represent functional connection and/or physical or circuit connections and may be replaceable or represented as various additional functional connections, physical connections, or circuit connections in an actual device.

The use of all examples or exemplary terms is merely for describing a technical idea in detail and the scope is not limited to the Examples or exemplary terms unless limited by the claims.

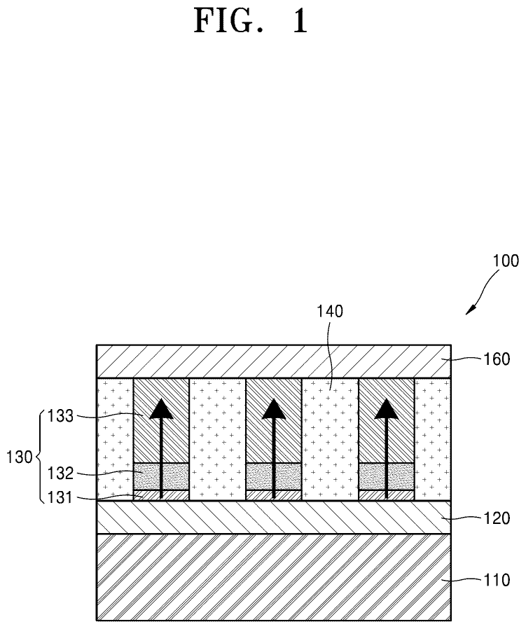

FIG. 1 is a perspective view illustrating a semiconductor device according to an embodiment.

Referring to FIG. 1, a semiconductor device 100 may include a channel layer 110, a first interface layer 120 on the channel layer 110, a plurality of ferroelectric layers 130 spaced apart from each other on the first interface layer 120, and a gate electrode 160 on the plurality of ferroelectric layers 130.

A channel element corresponding to the gate electrode 160 may be formed in the channel layer 110, and a source region and a drain region may be formed on both sides of the channel element, respectively. The source region and the drain region may be electrically connected to a source electrode (not shown) and a drain electrode (not shown), respectively.

The channel layer 110 may include a semiconductor material. The channel layer 110 may include, for example, a group IV semiconductor such as Si, Ge, SiGe, or the like, or may include a group III-V semiconductor compound. The channel layer 110 may include, for example, oxide semiconductors, nitride semiconductors, oxynitride semiconductors, two-dimensional (2D) semiconductor materials, quantum dots, or organic semiconductors. However, this is for illustrative purposes only, and this embodiment is not limited thereto. The channel layer 110 may further include a dopant. The dopant may include a p-type dopant or an n-type dopant. The p-type dopant may include, for example, a Group III element such as B, Al, Ga, In, or the like, and the n-type dopant may include, for Example, a Group V element such as P, As, Sb, or the like. The channel layer 110 may be integrally formed with the semiconductor substrate or may be formed separately from the semiconductor substrate.

The first interface layer 120 may include a dielectric material. The first interface layer 120 may include a high-k material. For example, the first interface layer 120 may include at least one of hafnium oxide, zirconium oxide, tantalum oxide, and titanium oxide, but is not limited thereto. The first interface layer 120 may include a low-k material. Specifically, the first interface layer 120 may include at least one of silicon oxide, silicon oxycarbide, and boron nitride, but is not limited thereto.

The ferroelectric layer 130 includes a crystalline material, and may include a first layer 131, a second layer 132, and a third layer 133 sequentially stacked. In other words, the second layer 132 may be arranged between the first layer 131 and the third layer 133. The first layer 131, the second layer 132, and the third layer 133 may be sequentially stacked in a direction perpendicular to the channel layer.

The ferroelectric layer 130 may include a ferroelectric. The ferroelectric is a ferroelectric material having ferroelectricity in which internal electric dipole moments are aligned to maintain spontaneous polarization. The ferroelectric has remnant polarization due to dipoles even in a state where an electric field is not applied from the outside. In the ferroelectric, the direction of polarization may be switched in units of domains by an external electric field.

The ferroelectric layer 130 may include, for example, a fluorite-based material. As a specific example, the ferroelectric layer 130 may include at least one of hafnium oxide (HfO₂), zirconium oxide (ZrO₂), and hafnium-zirconium oxide (HfxZr₁₋ₓO₂ (0<x<1). The ferroelectric layer 130 may further include a predetermined dopant. The dopant may include, for example, at least one of La, Y, Gd, Si, Al, Mg, Sr, and Ba, but is not limited thereto. The ferroelectric layer 130 may include at least one of an orthorhombic crystal system crystalline phase, a tetragonal crystal system crystalline phase, and a monoclinic crystal system crystalline phase. For example, the ferroelectric layer 130 may include the orthorhombic crystal system crystalline phase dominantly or at the largest ratio of all crystalline phases.

Among the first layer 131, the second layer 132, and the third layer 133, the third layer 133 may have the largest thickness. The thickness of the third layer 133 may be greater than the sum of the thicknesses of the first layer 131 and the second layer 132. The thickness of the first layer 131 may be greater than the thickness of the second layer 132. The thickness of the first layer 131 may be about 1.5 times or more, about 2 times or more, or about 3 times or more of the thickness of the second layer 132. The thickness of the first layer 131 may be about 7 times or less, or about 10 times or less, of the thickness of the second layer 132.

The first layer 131 may include, for example, zirconium oxide. The thickness of the first layer 131 may be, for example, in a range of about 5 Å to about 20 Å. The second layer 132 may include, for example, hafnium oxide. The thickness of the second layer 132 may be, for example, in a range of about 0 Å to about 15 Å. The total thickness of the first layer 131 and the second layer 132 may be, for example, in a range of about 0 Å to about 20 Å. The third layer 133 may include HfO₂ and hafnium-zirconium oxide (HZO), which is a solid solution of HfO₂ and ZrO₂. The third layer 133 may include, for example, HfZrO₂. The thickness of the third layer 133 may be, for example, in a range of about 0 Å to about 20 Å.

Since the ferroelectric layer 130 includes the first layer 131 including zirconium oxide, the second layer 132 including hafnium oxide, and the third layer 133 including HZO, a dispersion of electrical characteristics of the semiconductor device 100 may be improved.

Referring to FIG. 1, the crystalline direction of the ferroelectric layer 130 may be aligned in a same direction. The crystalline direction of the ferroelectric layer 130 may be aligned, for example, in a direction (001). The ferroelectric layer 130 may have a crystalline phase aligned in a direction (001) of an out-of-plane reference. The crystalline direction (001) may be substantially the same as the thickness direction of the ferroelectric layer 130. Thus, in a semiconductor device in which a gate electrode is formed on the ferroelectric layer 130 according to an embodiment, the gate voltage direction and the crystalline direction (001) are substantially the same, so that the polarization value of the semiconductor device may be increased. The crystalline direction of the ferroelectric layer 130 may be confirmed through X-ray diffraction (XRD) analysis. For example, if the XRD analysis of in-plane causes peaks to appear simultaneously in the directions (010) and (110), it may be considered to have the crystalline direction (001) in an out-of-plane reference. Specifically, in the hafnium oxide layer, the zirconium oxide layer, and the hafnium-zirconium oxide layer, a peak may appear in the direction (010) at 6±1°, and a peak may appear in the direction (110) at 12±1°, in the results of the in-plane XRD analysis.

The ferroelectric layer 130 may include a crystalline phase, a plurality of ferroelectric layers 130 may be provided, and a semiconductor device may include a low-k material layer 140 provided between the plurality of ferroelectric layers 130.

In other words, the semiconductor device 100 may further include the low-k material layer 140 provided to fill between the plurality of ferroelectric layers 130. The low-k material layer 140 may include a low-k material. The low-k material layer 140 may include a material having a dielectric constant lower than that of a ferroelectric material. The low-k material layer 140 may include a material having a dielectric constant of 1 to 3.9. The low-k material layer 140 may include, for example, at least one of SiO₂ and SiOC, but is not limited thereto. As the plurality of ferroelectric layers 130 and the low-k material layer 140 are mixed and provided, polarization may be maximized and capacitance may be reduced.

The ferroelectric layer 130 and the low-k material layer 140 may be included in an area ratio (area %) of about 20:80 to about 80:20 on a same plane.

The gate electrode 160 may include a conductive material. The gate electrode 160 may include, for example, a metal, a metal nitride, a metal oxide, polysilicon, or the like. As a specific example, the gate electrode 160 may include at least one of W, TiN, TaN, WN, NbN, Mo, Ru, Ir, RuO, IrO, and highly doped polysilicon.

The gate electrode 160 may include a metal carbide or a two-dimensional conductive material. The metal carbide may be a metal carbide doped with aluminum or silicon. As a specific example, the metal carbide may include TiAlC, TaAlC, TiSiC, or TaSiC. The gate electrode 160 may have a structure in which a plurality of materials are stacked. For example, the gate electrode 160 may have a stacked structure of a metal nitride layer/metal layer such as TiN/Al or a stacked structure of a metal nitride layer/metal carbide layer/metal layer such as TiN/TiAlC/W.

The ferroelectric layer 130 of the semiconductor device 100 according to an embodiment may include a crystalline material and may maximize polarization by including the first layer 131, the second layer 132, and the third layer 133 sequentially stacked. In addition, the memory window of the semiconductor device 100 may be increased by reducing the capacitance of the ferroelectric layer 130.

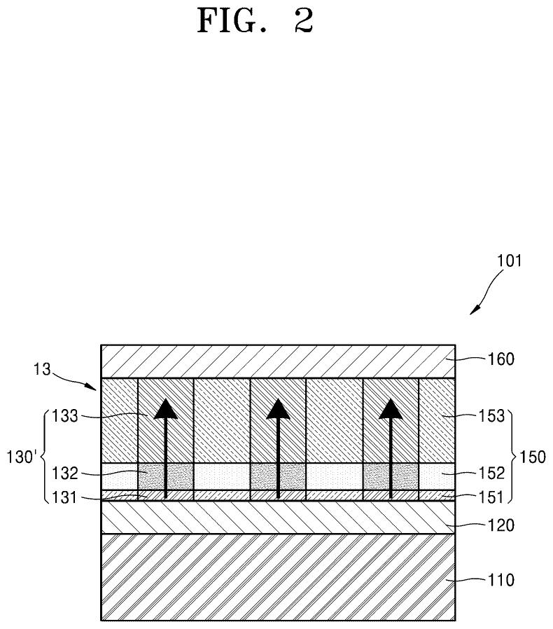

Referring to FIG. 2, a semiconductor device 101 may include a channel layer 110, a first interfacial layer 120 on the channel layer 110, a ferroelectric layer 130 on the first interfacial layer 120, and a gate electrode 160 on the ferroelectric layer 130.

The semiconductor device 101 of FIG. 2 may be the same as the semiconductor device 100 of FIG. 1 except for the feature of a ferroelectric layer. In describing FIG. 2, redundant descriptions of FIG. 1 are omitted.

The ferroelectric layer 130 may include a plurality of crystalline phases including a first layer 131, a second layer 132, and a third layer 133, and may include an amorphous phase 150 provided between the plurality of crystalline phases 130′. The amorphous phase 150 may include a first amorphous layer 151 including zirconium oxide, a second amorphous layer 152 including hafnium oxide, and a third amorphous layer 153 including hafnium oxide.

The crystalline phases 130′ may include at least one of an orthorhombic crystal system crystalline phase, a tetragonal crystal system crystalline phase, and a monoclinic crystal system crystalline phase. For example, the crystalline phase 130′ may be an orthorhombic crystal system crystalline phase.

The crystalline direction of the crystalline phase 130′ may be a direction (001).

The first amorphous layer 151, the second amorphous layer 152, and the third amorphous layer 153 may correspond to the first layer 131, the second layer 132, and the third layer 133, respectively. For example, the first amorphous layer 151 and the first layer 131 may have substantially the same material composition, thickness, and the like, except for whether the first amorphous layer 151 and the first layer 131 are an amorphous phase and a crystalline phase, respectively.

The thickness of the first amorphous layer 151 may be, for example, in a range of about 5 Å to about 20 Å. The thickness of the second amorphous layer 152 may be, for example, in a range of about 0 Å to about 15 Å. The thickness of the third amorphous layer 153 may be, for example, in a range of about 20 Å to about 100 Å.

The amorphous phase 150 may have a material composition different from that of the crystalline phase 130′. For example, the amorphous phase 150 may include a low-k material. The low-k material may include a material having a dielectric constant lower than that of a ferroelectric material. The low-k material may include a material having a dielectric constant of 1 to 3.9. The low-k material may include, for example, at least one of SiO₂ and SiOC, but is not limited thereto.

The ferroelectric layer 130 may include the crystalline phase 130′ and the amorphous phase 150 in a volume ratio (vol %) of about 20:80 to about 80:20.

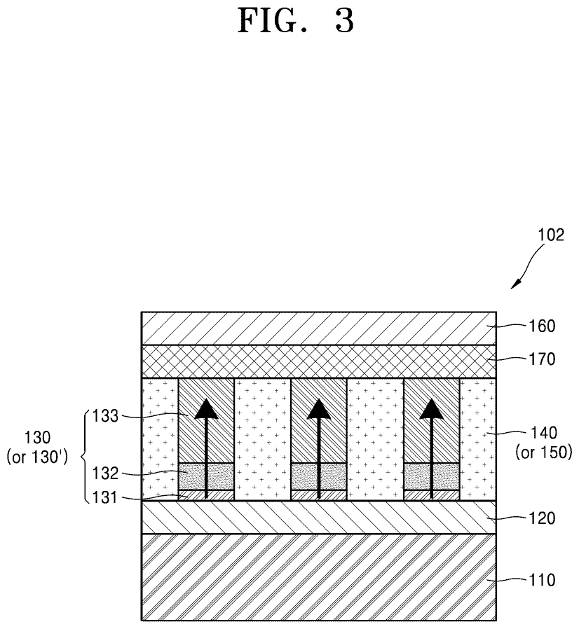

As the plurality of crystalline phases and amorphous phases are mixed and provided, polarization may be maximized and capacitance may be reduced. FIG. 3 is a cross-sectional view illustrating a semiconductor device according to an embodiment.

Referring to FIG. 3, a semiconductor device 102 may include a channel layer 110, a first interface layer 120 on the channel layer 110, a plurality of ferroelectric layers 130 spaced apart from each other on the first interface layer 120, a gate electrode 160 on the plurality of ferroelectric layers 130, and a second interface layer 170 between the plurality of ferroelectric layers 130 and the gate electrode 160.

The semiconductor device 102 of FIG. 3 may be the same as the semiconductor device 100 of FIG. 1 except that the semiconductor device 102 further includes the second interface layer 170 provided between the plurality of ferroelectric layers 130 and the gate electrode 160. In describing FIG. 3, redundant descriptions of FIG. 1 are omitted.

The second interface layer 170 may include a high-k material. For example, the second interface layer 170 may include at least one of hafnium oxide, zirconium oxide, tantalum oxide, and titanium oxide, but is not limited thereto. The second interface layer 170 may include a low-k material. Specifically, the second interface layer 170 may include at least one of silicon oxide, silicon oxycarbide, and boron nitride, but is not limited thereto.

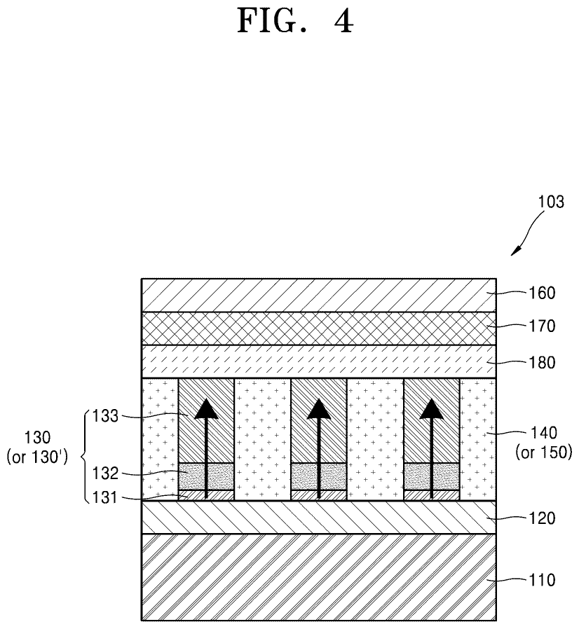

FIG. 4 is a cross-sectional view illustrating a semiconductor device according to an embodiment.

Referring to FIG. 4, a semiconductor device 103 may include a channel layer 110, a first interface layer 120 on the channel layer 110, a ferroelectric layer 130 on the first interface layer 120, a gate electrode 160 on the ferroelectric layer 130, a second interface layer 170 between the ferroelectric layer 130 and the gate electrode 160, and a charge trap layer 180 between the second interface layer 170 and the ferroelectric layer 130. Alternatively, the charge trap layer 180 may be provided between the first interface layer 120 and the ferroelectric layer 130. The charge trap layer 180 may be in contact with the ferroelectric layer 130.

The charge trap layer 180 may be an amorphous material. The charge trap layer 180 may have a large bandgap energy and a deep trap level. For example, the charge trap layer 180 may have a bandgap energy of 4 eV or more, and may have a deep trap level lower by 1.0 eV or more or 1.5 eV or more than a conduction band. The charge trap layer 180 may include nitride or oxynitride. For example, the charge trap layer 180 may include one or more of aluminum (oxy)nitride, gallium (oxy)nitride, germanium (oxy)nitride, silicon (oxy)nitride, indium (oxy)nitride, scandium (oxy)nitride, and zirconium (oxy)nitride. The charge trap layer 180 may include silicon nitride or silicon oxynitride.

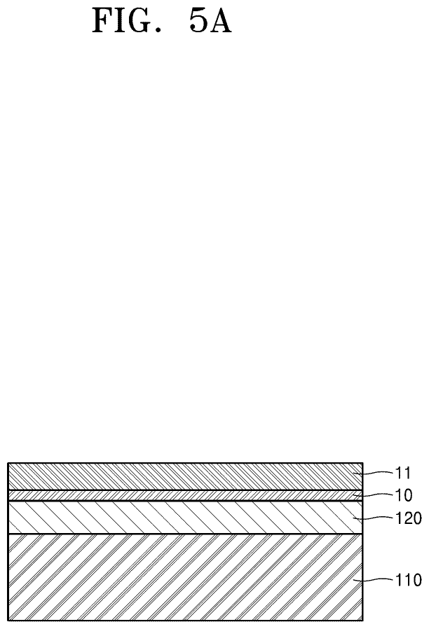

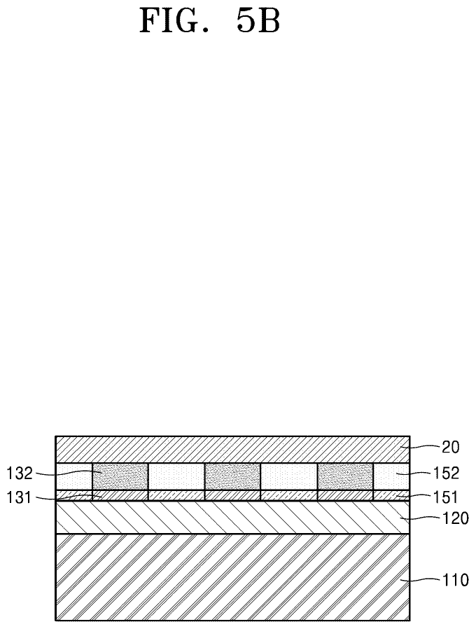

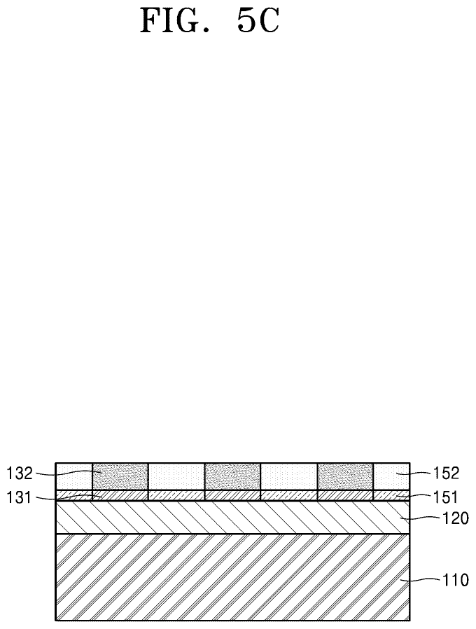

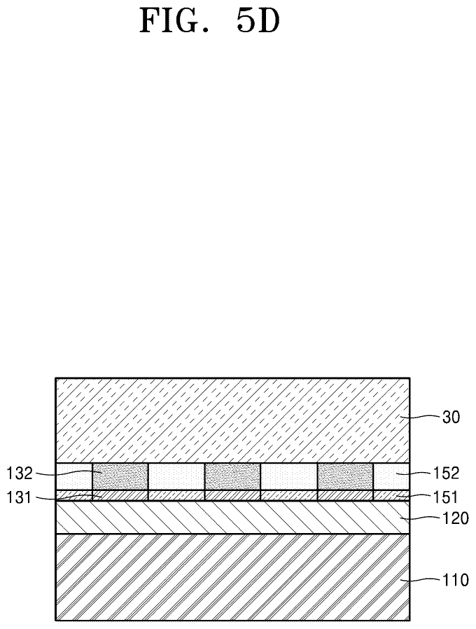

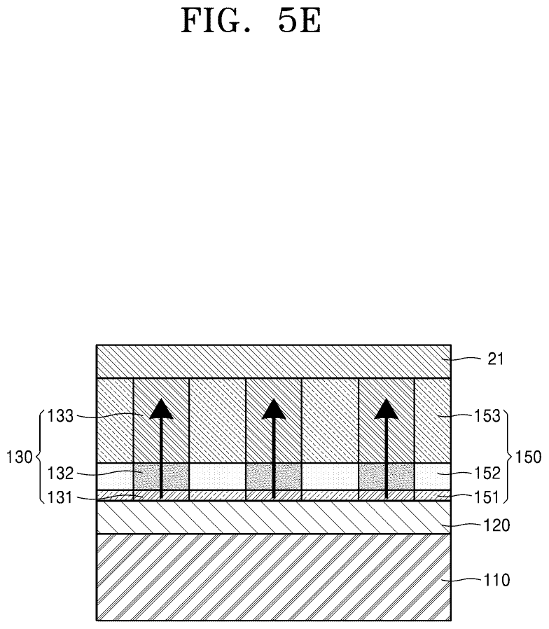

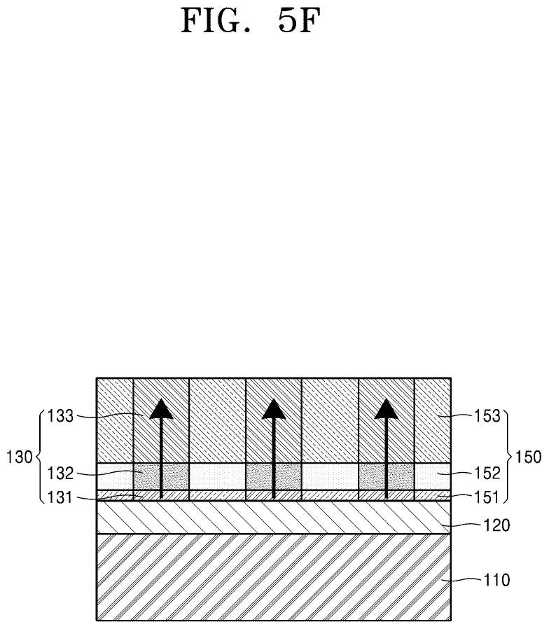

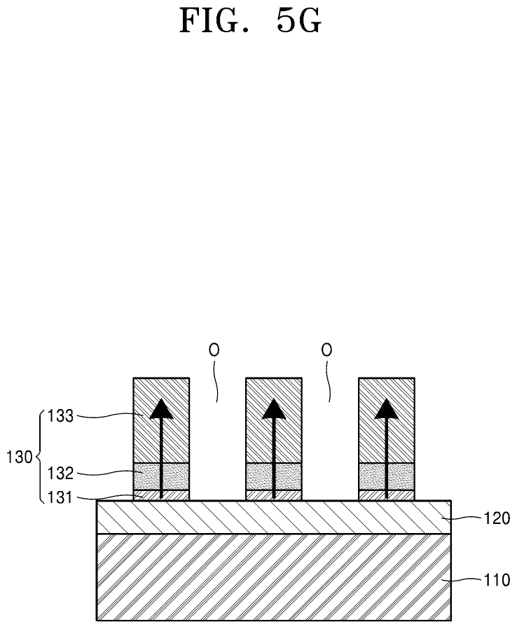

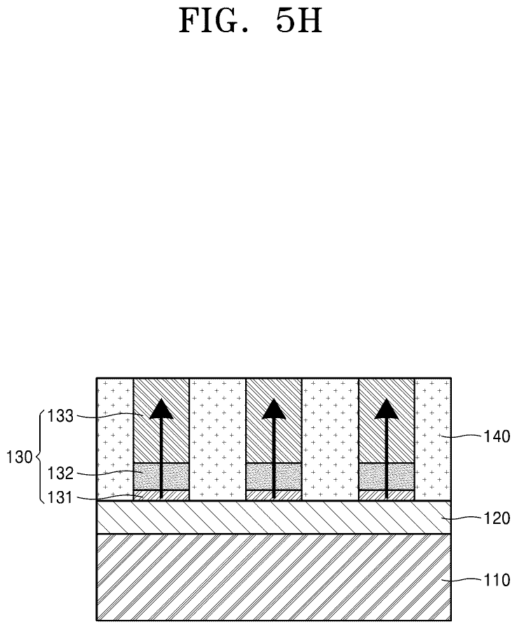

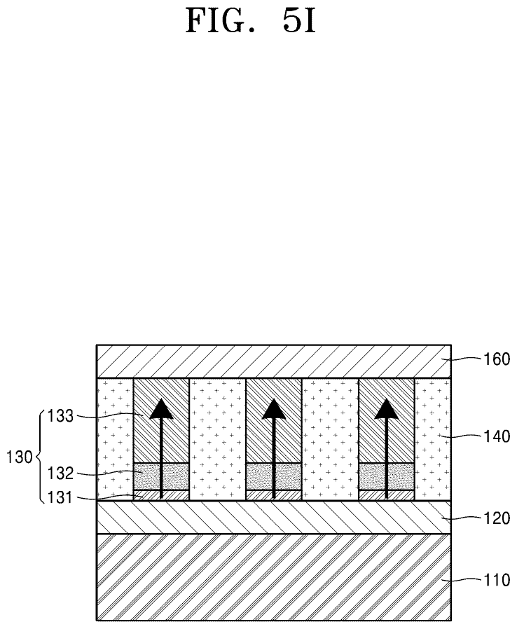

FIGS. 5A to 5I are diagrams illustrating a method of manufacturing a semiconductor device according to an embodiment. In describing FIGS. 5A to 5I, redundant descriptions of FIG. 1 are omitted.

Referring to FIG. 5A, an interface layer 120 may be formed on a channel layer 110, and a first precursor layer 10 and a second precursor layer 11 may be sequentially formed on the interface layer 120. The first precursor layer 10 may include, for example, zirconium oxide. The second precursor layer 11 may include, for example, hafnium oxide. The first precursor layer 10 and the second precursor layer 11 may include an amorphous material.

The first precursor layer 10 and the second precursor layer 11 may cross-deposit a hafnium source (or a zirconium source) and an oxygen source by an atomic layer deposition method. After deposition, a purging operation may be further performed.

Conventional precursors may be used as the hafnium source, the zirconium source, and the oxygen source. For example, at least one selected from the group consisting of Hf(OtBu)₄, Tetrakis Ethyl Methyl Amino Hafnium (TEMAH), Tetrakis Di-Methyl Amino Hafnium (TDMAH), Tetrakis Di-Ethyl Amino Hafnium (TDEAH), and combinations thereof may be used as the hafnium source, but embodiments are not limited thereto. In addition, at least one selected from the group consisting of Zr(OtBu)₄, Tetrakis Ethyl Methyl Amino Zirconium (TEMAZ), Tetrakis Di-Methyl Amino Zirconium (TDMAZ), Tetrakis Di-Ethyl Amino Zirconium (TDEAZ), and combinations thereof may be used as the zirconium source, but embodiments are not limited thereto. In addition, at least one selected from the group consisting of O₃, H₂O, O₂, N₂O, O₂ plasma, and combinations thereof may be used as the oxygen source, but embodiments are not limited thereto.

Referring to FIG. 5B, at least one of the first precursor layer 10 and the second precursor layer 11 may be annealed. Some portions of the first precursor layer 10 and the second precursor layer 11 may be crystallized through annealing. A first metal layer 20 may include, for example, Pt, Nb, Ru, Mo, W, or TiN.

The annealing of any one or more of the first precursor layer 10 and the second precursor layer 11 may be performed after the formation of the first precursor layer 10. The annealing of any one or more of the first precursor layer 10 and the second precursor layer 11 may be performed after the formation of the first precursor layer 10 and the second precursor layer 11. The annealing of any one or more of the first precursor layer 10 and the second precursor layer 11 may be performed after the formation of the first precursor layer 10 and may be performed again after the formation of the second precursor layer 11. The annealing of any one or more of the first precursor layer 10 and the second precursor layer 11 may be performed at a temperature condition of about 350° C. to about 600° C., may be performed for about 0.5 seconds or more, about 1 second or more, about 3 seconds or more, or about 5 seconds or more, and may be performed for about 1 minute or less, about 5 minutes or less, or about 10 minutes or less.

The annealing of any one or more of the first precursor layer 10 and the second precursor layer 11 may be performed before forming the first metal layer 20 on the second precursor layer 11, after forming the first metal layer 20 thereon, or both before and after forming the first metal layer 20 on the second precursor layer 11.

The annealing of any one or more of the first precursor layer 10 and the second precursor layer 11 may be performed such that some portions of the first precursor layer 10 and the second precursor layer 11 are crystallized. A crystallized region of the first precursor layer 10 (see FIG. 5A) may be the first layer 131, and an uncrystallized region may be the first amorphous layer 151. A crystallized region of the second precursor layer 11 (see FIG. 5A) may be the second layer 132, and an uncrystallized region may be the second amorphous layer 152.

Referring to FIGS. 5C and 5D, the first metal layer 20 may be removed, and a third precursor layer 30 may be formed on the second precursor layer 11 (see FIG. 5A). The third precursor layer 30 may include hafnium zirconium oxide. The third precursor layer 30 may cross-deposit a hafnium source (or a zirconium source) and an oxygen source by an atomic layer deposition method. After deposition, a purging operation may be further performed.

Referring to FIG. 5E, some portions of the third precursor layer 30 (see FIG. 5D) may be crystallized by annealing the third precursor layer 30 (see FIG. 5D).

The annealing of the third precursor layer 30 (see FIG. 5D) may be performed before the second metal layer 21 is formed on the third precursor layer 30, after the second metal layer 21 is formed thereon, or both before and after the second metal layer 21 is formed on the third precursor layer 30.

A crystallized region of the third precursor layer 30 (see FIG. 5D) may be the third layer 133, and an uncrystallized region may be the third amorphous layer 153. The first layer 131, the second layer 132, and the third layer 133 may be referred to as the ferroelectric layer 130 or the crystalline phase 130′, and the first amorphous layer 151, the second amorphous layer 152, and the third amorphous layer 153 may be referred to as the amorphous phase 150.

The annealing of the third precursor layer 30 (see FIG. 5D) may be performed such that the first precursor layer 10 (see FIG. 5A), the second precursor layer 11 (see FIG. 5A), and the third precursor layer 30 (see FIG. 5D) have an orthorhombic crystal system crystalline structure dominantly. The annealing of the third precursor layer 30 (see FIG. 5D) may be performed such that a crystalline direction of the ferroelectric layer 130 is aligned in a direction (001). In FIG. 5E, arrows illustrate a schematic diagram of alignment of the ferroelectric layer 130 or the crystalline phase 130′ in the crystalline direction. The annealing of the third precursor layer 30 (see FIG. 5D) may be performed such that the crystalline directions of the first layer 131, the second layer 132, and the third layer 133 are aligned in the direction (001). The annealing of the third precursor layer 30 (see FIG. 5D) may be performed under a temperature condition of 350° C. to 600° C. The annealing of the third precursor layer 30 (see FIG. 5D) may be performed for about 0.5 seconds or more, about 1 second or more, about 3 seconds or more, or about 5 seconds or more, and may be performed for about 1 minute or less, about 5 minutes or less, or about 10 minutes or less.

Referring to FIGS. 5F and 5G, the second metal layer 21 may be removed, and uncrystallized portions of the first precursor layer 10 (see FIG. 5A), the second precursor layer 11 (see FIG. 5A), and the third precursor layer 30 (see FIG. 5D) may be selectively etched. In the etching operation, at least some portions of the uncrystallized portions of the first precursor layer 10 (see FIG. 5A), the second precursor layer 11 (see FIG. 5A), and the third precursor layer 30 (see FIG. 5D) may be selectively etched to form an etched region O (see FIG. 5G). The etched region O may be an opening that extends through a remaining portion of the first precursor layer 10, a remaining portion of the second precursor layer 20, and a remaining portion of the third precursor layer 30 after the etching operation. The remaining portion of the first precursor layer 10, the remaining portion of the second precursor layer 20, and the remaining portion of the third precursor layer 30, after the forming the etched region O, may correspond to the first layer 131, the second layer 132, and the third layer 133 in FIG. 5G. At least some portions of the amorphous phase 150, that is, the first amorphous layer 151, the second amorphous layer 152, and the third amorphous layer 153 may be etched. The etched region O may correspond to the portions of the amorphous phase 150 (e.g., the first amorphous layer 151, the second amorphous layer 152, and the third amorphous layer 153) that are removed in the etching operation.

As another example, the second metal layer 21 may be removed, and a portion of the ferroelectric layer 130 may be selectively etched. The selective etching may be performed using a mask pattern. After etching, a plurality of ferroelectric layers 130 spaced apart from each other may be formed.

Referring to FIG. 5H, a low-k material layer 140 may be formed in regions where the first precursor layer 10 (see FIG. 5A), the second precursor layer 11 (see FIG. 5A), and the third precursor layer 30 (see FIG. 5D) have been etched. The low-k material layer 140 may be provided to fill between the plurality of ferroelectric layers 130.

Referring to FIG. 5I, a gate electrode 160 may be formed on the low-k material layer 140 and the third layer 133. The gate electrode 160 may be provided on the plurality of ferroelectric layers 130.

Meanwhile, after the operation of FIG. 5E, the second metal layer 21 may be removed, and the gate electrode 160 (see FIG. 5I) may be formed on the third precursor layer 30 (see FIG. 5D). Alternatively, the second metal layer 21 may be applied as the gate electrode 160 without removing the second metal layer 21.

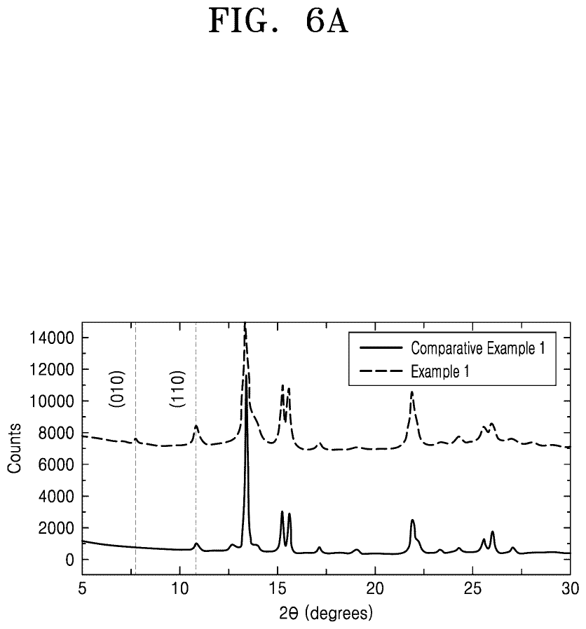

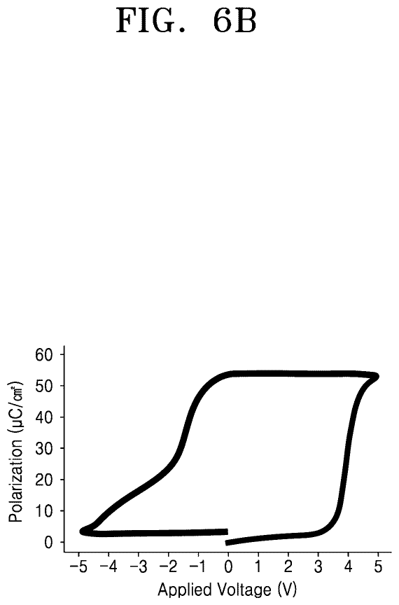

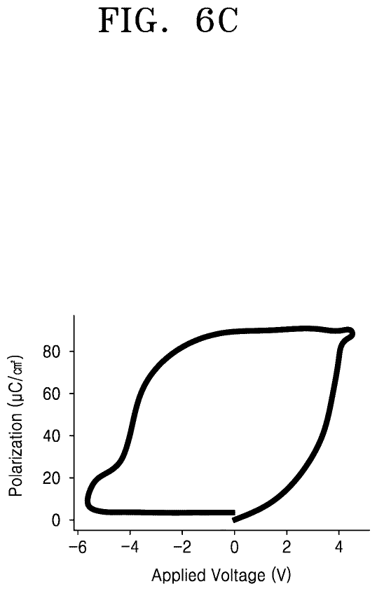

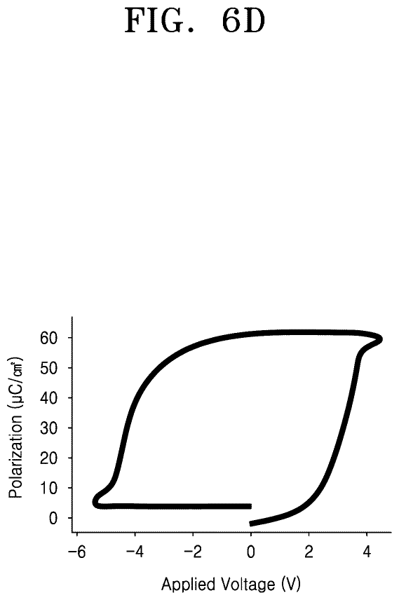

FIG. 6A is in-plane X-ray diffraction (XRD) data of a ferroelectric layer of a semiconductor device according to an Example 1 and a Comparative Example 1.

In the ferroelectric layer of an Example 1, a zirconium oxide layer was formed at about 16 Å, a hafnium oxide layer was formed at about 4 Å on the zirconium oxide layer, and then a heat treatment was performed at about 450° C., and a metal layer was deposited, and then a heat treatment was performed at about 350° C. After removing the metal layer, HZO was deposited by about 50 Å thereon, the metal layer was further deposited, and then heat treatment was performed at about 500° C. to form a ferroelectric layer of about 7 nm. In the ferroelectric layer according to a Comparative Example 1, only about 7 nm of HZO was deposited, a metal layer was further deposited, and then heat treatment was performed at about 500° C. to form a ferroelectric layer of about 7 nm. An atomic layer deposition method was used for the zirconium oxide layer, the hafnium oxide layer, and the hafnium zirconium oxide layer.

Referring to FIG. 6A, in the case of the ferroelectric layer according to the Example 1, it may be seen that a peak in the direction (010) is activated around 6° and a peak in the direction (110) is activated around 12°. In the case of the ferroelectric layer according to the Comparative Example 1, a peak in the direction (010) around 6° is not substantially confirmed. The simultaneous activation of the (010) peak and the (110) peak of the in-plane reference means that the crystalline phase is aligned in the direction (001) of the out-of-plane reference. In other words, the ferroelectric layer according to the Example (e.g., Example 1) includes a crystalline phase in the direction (001) of the out-of-plane reference.

FIGS. 6B and 6D are graphs illustrating a P-V curve of a semiconductor device according to Comparative Examples. FIG. 6C is a graph illustrating a P-V curve of a semiconductor device according to an Example 2. Semiconductor devices according to the Examples and Comparative Examples were manufactured by forming a ferroelectric layer on silicon substrate and then forming a molybdenum gate electrode thereon. During the manufacturing process, a silicon oxide interface layer may be formed on the silicon substrate. The ferroelectric layers of an Example 2 of FIG. 6C and a Comparative Example 2 of FIG. 6B were formed in the same manner as in the Example 1 and the Comparative Example 1 of FIG. 6A, and the ferroelectric layer of a Comparative Example 3 of FIG. 6D was formed in the same manner as in the Example 1 of FIG. 6A, except that the zirconium oxide layer was formed to be about 20 Å and the hafnium oxide layer was not formed in the ferroelectric layer of a Comparative Example 3 of FIG. 6D.

Referring to FIGS. 6B and 6D, in the case of semiconductor devices according to a Comparative Example 2 of FIG. 6B and a Comparative Example 3 of FIG. 6D, the polarization values (Pᵣ) are about 51 μC/cm² and about 60 μC/cm², respectively. In addition, referring to FIG. 6C, it may be confirmed that the polarization value (Pᵣ) of the semiconductor device according to the Example 2 of FIG. 6C has a value of about 90 μC/cm². That is, it may be seen that the polarization value of the semiconductor device according to the Examples (e.g., Example 2) is much greater.

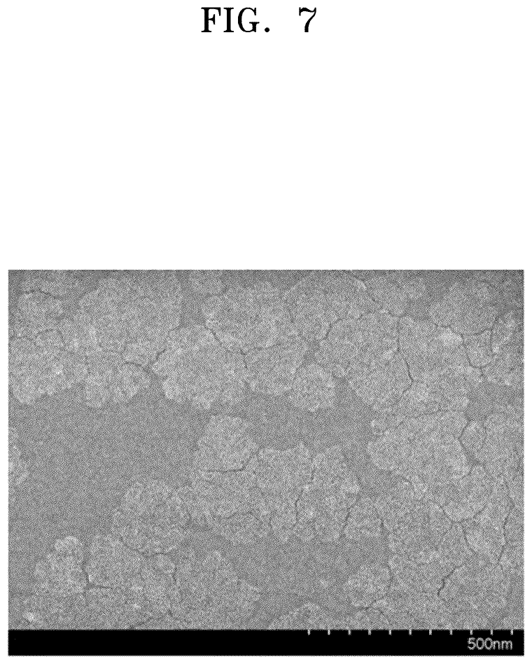

FIG. 7 is a scanning electron microscope (SEM) image of a ferroelectric layer according to the Example 1.

Referring to FIG. 7, it may be seen that the crystal grains of the ferroelectric layer are formed discontinuously. Through this, it may be confirmed that the ferroelectric layer according to the Examples includes a crystalline phase and an amorphous phase.

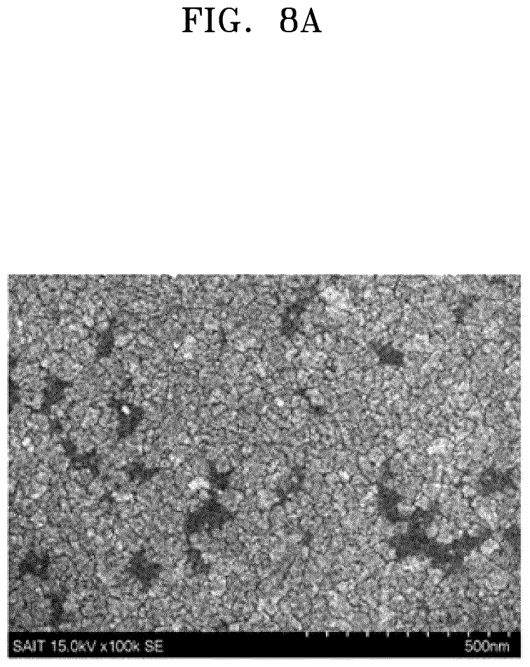

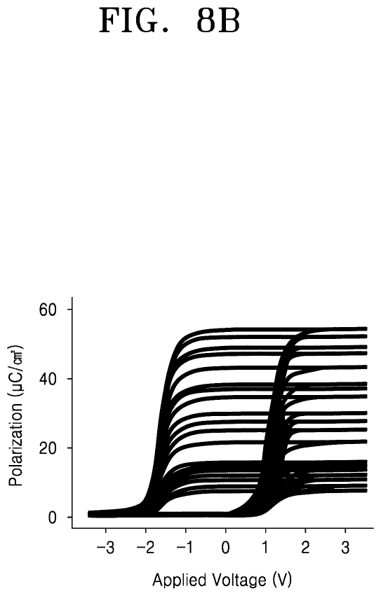

FIG. 8A is a scanning electron microscope (SEM) image of the surface of a ferroelectric layer according to the Comparative Example 1. FIG. 8B is a graph showing a P-V curve of a semiconductor device including a ferroelectric layer according to the Comparative Example 3. The semiconductor device of the Comparative Example 3 was manufactured by forming a ferroelectric layer on a molybdenum electrode and then forming a molybdenum electrode thereon. The ferroelectric layer was formed by depositing only about 7 nm of HZO in the same manner as in Comparative Example 1 and performing heat treatment at about 350° C. for about 30 seconds.

Referring to FIGS. 8A and 8B, it may be seen that the ferroelectric layer according to Comparative Example 1 includes both a crystalline phase and an amorphous phase, but the semiconductor device of Comparative Example 3 including the ferroelectric layer according to Comparative Example 1 has a large dispersion of electrical characteristics and a small polarization value. In contrast, a semiconductor device according to an embodiment, may have a small dispersion of electrical characteristics and a higher polarization value.

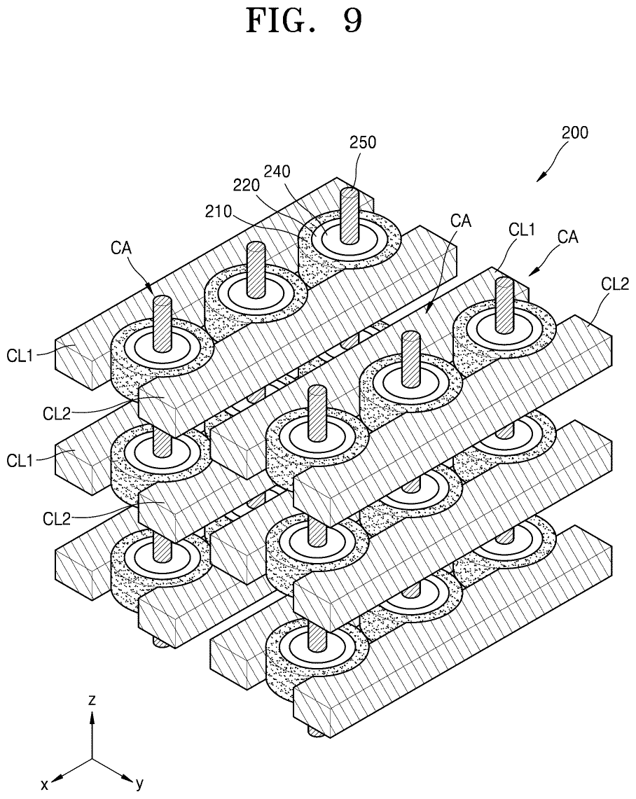

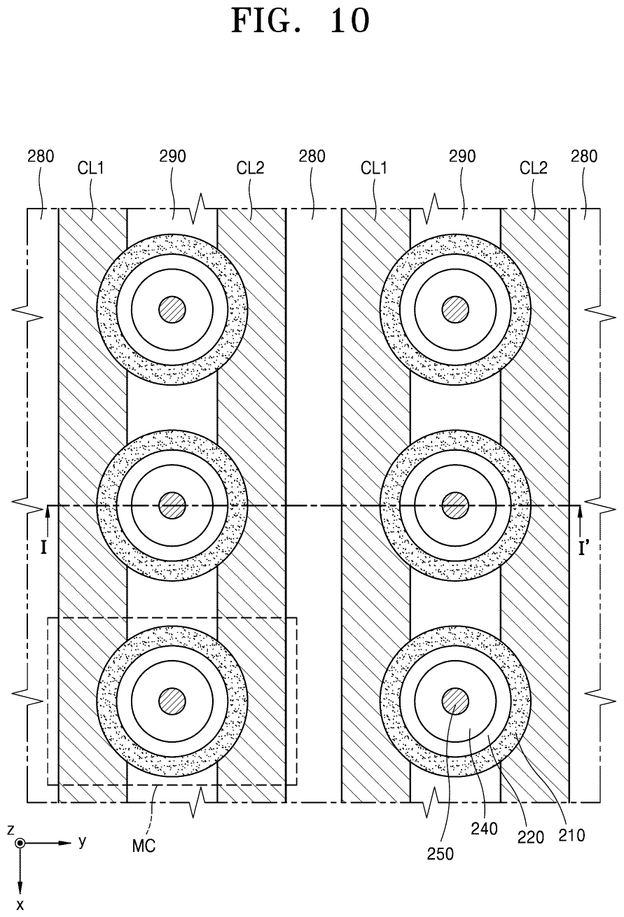

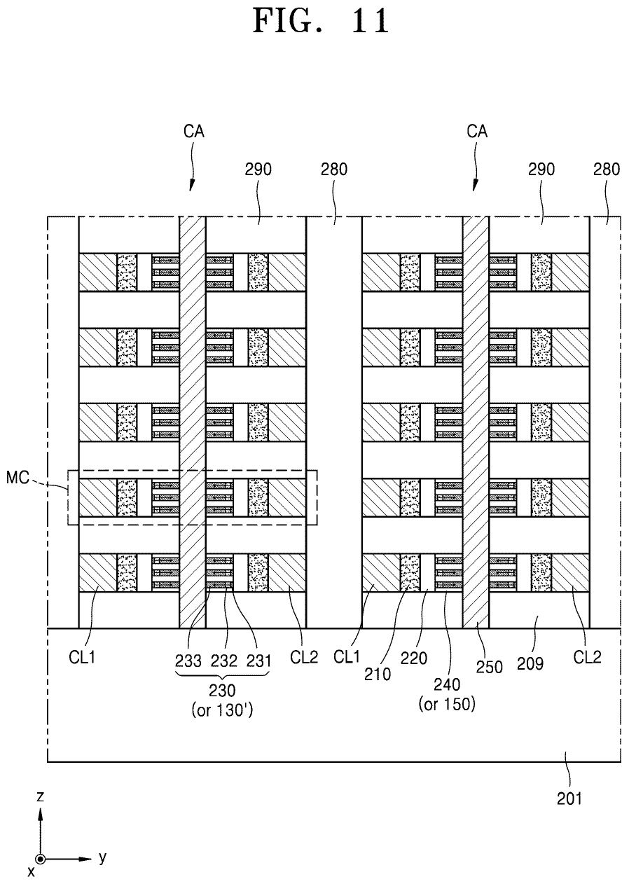

FIG. 9 is a perspective view illustrating a memory device according to an embodiment. FIG. 10 is a plan view of the memory device illustrated in FIG. 9. FIG. 11 is a cross-sectional view taken along line I-I′ of FIG. 10. Hereinafter, differences from the embodiments described above are mainly described.

Referring to FIGS. 9 to 11, a memory device 200 includes a plurality of cell arrays CA arranged two-dimensionally on a substrate 201. FIG. 9 illustrates an Example in which the plurality of cell arrays CA are arranged in a first direction (x-axis direction) and a second direction (y-axis direction) parallel to the substrate 201.

Each of the cell arrays CA may be provided to extend in a direction (z-axis direction) perpendicular to the substrate 201. Each of the cell arrays CA may include a plurality of memory cells MC spaced apart from each other in a direction (z-axis direction) perpendicular to the substrate 201. Each of the memory cells MC may include any one the semiconductor devices 100, 101, 102 and 103 according to the embodiments described with reference to FIGS. 1 to 4.

A first conductive line CL1 and a second conductive line CL2 are respectively provided on both sides of the plurality of memory cells MCs spaced apart from each other in the first direction (x-axis direction) parallel to the substrate 201. For example, the first and second conductive lines CL1 and CL2 may be a source electrode and a drain electrode, respectively. The first and second conductive lines CL1 and CL2 may be shared by the memory cells MCs arranged in the first direction (x-axis direction), respectively. A first insulating material 280 may be provided between the cell arrays CA arranged to be spaced apart from each other in a second direction (y-axis direction) parallel to the substrate 201. In addition, a second insulating material 290 may be provided between the memory cells MC spaced apart from each other in a direction (z-axis direction) perpendicular to the substrate 201. In addition, the second insulating material 290 may be provided to fill a space between the first and second conductive lines CL 1 to CL 2 while surrounding the memory cells MC.

The substrate 201 may include one or more various materials. For example, the substrate 201 may include a single crystal silicon substrate, a compound semiconductor substrate, or a silicon on insulator (SOI) substrate, but is not limited thereto. In addition, the substrate 201 may further include, for example, impurity areas by doping, electronic devices such as transistors, or peripheral circuits that select and control memory cells MC that store data.

Each of the memory cells MC has a structure in which a gate electrode 250, a plurality of ferroelectric layers 230 (see FIG. 11), an interface layer 220, and a channel layer 210 are sequentially stacked in a direction parallel to the substrate 201. The memory cell MC may further include the low-k material layer 240 provided to fill between the plurality of ferroelectric layers 230. Here, the gate electrode 250 is provided to extend vertically to the substrate 201 and may be shared by the memory cells MC constituting each of the cell arrays CA. Each of the plurality of ferroelectric layers 230, the interface layer 220, and the channel layer 210 may be formed in a cylindrical shape surrounding the gate electrode 250.

The gate electrode 250 may include a conductive material. The gate electrode 250 may include, for example, a metal, a metal nitride, a metal oxide, polysilicon, or the like. As a specific example, the gate electrode 250 may include at least one of W, TiN, TaN, WN, NbN, Mo, Ru, Ir, RuO, IrO, and highly doped polysilicon. The gate electrode 250 may include a metal carbide or a two-dimensional conductive material.

The channel layer 210 may include, for example, a group IV semiconductor such as Si, Ge, SiGe, or the like, or may include a group III-V semiconductor compound. The channel layer 210 may include, for example, oxide semiconductors, nitride semiconductors, oxynitride semiconductors, two-dimensional (2D) semiconductor materials, quantum dots, or organic semiconductors. However, this is for illustrative purposes only, and this embodiment is not limited thereto. The channel layer 210 may further include a dopant.

A plurality of ferroelectric layers 230 (see FIG. 11) are provided between the gate electrode 250 and the channel layer 210. The ferroelectric layer 230 may include a ferroelectric. The ferroelectric is a ferroelectric material having ferroelectricity in which internal electric dipole moments are aligned to maintain spontaneous polarization. The ferroelectric has remnant polarization due to dipoles even in a state where an electric field is not applied from the outside. In the ferroelectric, the direction of polarization may be switched in units of domains by an external electric field.

The ferroelectric layer 230 may include at least one of an orthorhombic crystal system crystalline phase, a tetragonal crystal system crystalline phase, and a monoclinic crystal system crystalline phase. For example, the ferroelectric layer 230 may include the orthorhombic crystal system crystalline phase dominantly or at the largest ratio of all crystalline phases.

The ferroelectric layer 230 includes a crystalline material, and may include a first layer 231, a second layer 232, and a third layer 233 sequentially stacked. In other words, the second layer 232 may be arranged between the first layer 231 and the third layer 233. The first layer 231, the second layer 232, and the third layer 233 may be stacked in a direction perpendicular to the channel layer.

Among the first layer 231, the second layer 232, and the third layer 233, the third layer 233 may have the largest thickness. The thickness of the third layer 233 may be greater than the sum of the thicknesses of the first layer 231 and the second layer 232. The thickness of the first layer 231 may be greater than the thickness of the second layer 232. The thickness of the first layer 231 may be about 1.5 times or more, about 2 times or more, or about 3 times or more of the thickness of the second layer 232. The thickness of the first layer 231 may be about 7 times or less, or about 10 times or less, of the thickness of the second layer 232.

The first layer 231 may include, for example, zirconium oxide. The thickness of the first layer 231 may be, for example, in a range of about 5 Å to about 20 Å. The second layer 232 may include, for example, hafnium oxide. The thickness of the second layer 232 may be, for example, in a range of about 0 Å to about 15 Å. The total thickness of the first layer 231 and the second layer 232 may be, for example, in a range of about 0 Å to about 20 Å. The third layer 233 may include HZO, which is a solid solution of HfO₂ and ZrO₂. The third layer 233 may include, for example, HfZrO₂. The thickness of the third layer 233 may be, for example, in a range of about 0 Å to about 20 Å.

An interface layer 220 is provided between the channel layer 210 and the ferroelectric layer 230. The interface layer 220 may include a dielectric material. The interface layer 220 may include a high-k material. For example, the high-k material may include at least one of hafnium oxide, zirconium oxide, tantalum oxide, and titanium oxide, but is not limited thereto. The interface layer 220 may include a low-k material. Specifically, the interface layer 220 may include at least one of silicon oxide, silicon oxycarbide, and boron nitride, but is not limited thereto.

The low-k material layer 240 may include a low-k material. The low-k material layer 240 may include a low-k material. The low-k material layer 240 may include a material having a dielectric constant lower than that of a ferroelectric material. The low-k material layer 140 may include a material having a dielectric constant of 1 to 3.9. The low-k material layer 240 may include, for example, at least one of SiO₂ and SiOC, but is not limited thereto. As the plurality of ferroelectric layers 230 and the low-k material layer 240 are mixed and provided, polarization may be maximized and capacitance may be reduced.

In the memory device 200 according to an embodiment, the ferroelectric layers 230 may include a crystalline material, include a first layer 231, a second layer 232, and a third layer 233 sequentially stacked, and as a plurality of ferroelectric layers 230 and a low-k material layer 240 are mixed and provided, polarization of the ferroelectric layers 230 may be maximized, capacitance of the ferroelectric layers 230 may be reduced, and thus, a memory window of each memory cell MC may be increased.

In FIGS. 9 to 11, a case in which the plurality of ferroelectric layers 230, the interface layer 220, and the channel layer 210 sequentially surrounding the gate electrode 250 are separated for each memory cell MC in a direction (z-axis direction) perpendicular to the substrate 201 has been described. However, embodiments are not limited thereto, and all of the plurality of ferroelectric layers 230, the interface layer 220, and the channel layer 210 may be provided in common for the plurality of memory cells MC in a direction (z-axis direction) perpendicular to the substrate 201. In addition, some of the plurality of ferroelectric layers 230, the interface layer 220, and the channel layer 210 may be provided separately for each memory cell MC in a direction (z-axis direction) perpendicular to the substrate 201.

The semiconductor devices 100, 101, 102, and 103 and the memory device 200 according to the embodiments described above may be used for data storage in various electronic devices.

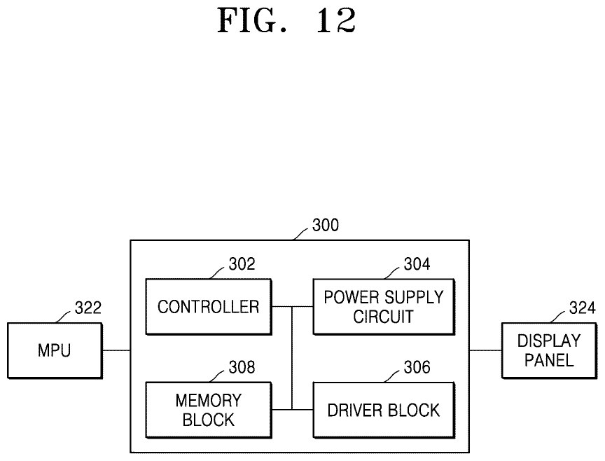

FIG. 12 is a schematic block diagram of a display driver IC (DDI) and a display device including the DDI according to an embodiment.

Referring to FIG. 12, the DDI 300 may include a controller 302, a power supply circuit 304, a driver block 306, and a memory block 308. The controller 302 receives and decodes a command applied from the main processing unit (MPU) 322, and controls each block of the DDI 300 to implement an operation according to the command. The power supply circuit 304 generates a driving voltage in response to the control of the controller 302. The driver block 306 drives the display panel 324 using the driving voltage generated by the power supply circuit 304 in response to the control of the controller 302. The display panel 324 may include a liquid crystal display panel or a plasma display panel. The memory block 308 is a block that temporarily stores commands input to the controller 302 or control signals output from the controller 302, or stores necessary data, and may include a memory such as random access memory (RAM) and read only memory (ROM). The power supply circuit 304 and the driver block 306 may include the semiconductor devices 100, 101, 102, and 103 according to the embodiments described above with reference to FIGS. 1 to 4 or the memory device 200 according to the embodiment described above with reference to FIGS. 9 to 11.

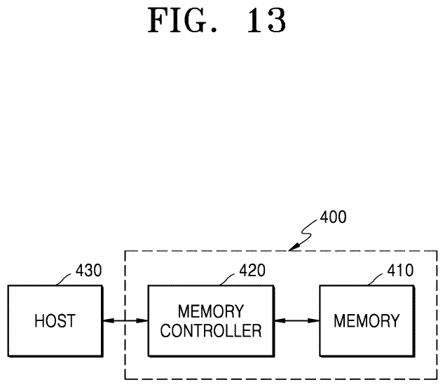

FIG. 13 is a block diagram of an electronic system including a semiconductor device according to an embodiment.

Referring to FIG. 13, an electronic system 400 includes a memory 410 and a memory controller 420. The memory controller 420 may control the memory 410 to read data from the memory 410 and/or write data to the memory 410 in response to a request from a host 430. At least one of the memory 410 and the memory controller 420 may include the semiconductor devices 100, 101, 102, and 103 according to the embodiments described above with reference to FIGS. 1 to 4 or the memory device 200 according to the embodiment described above with reference to FIGS. 9 to 11.

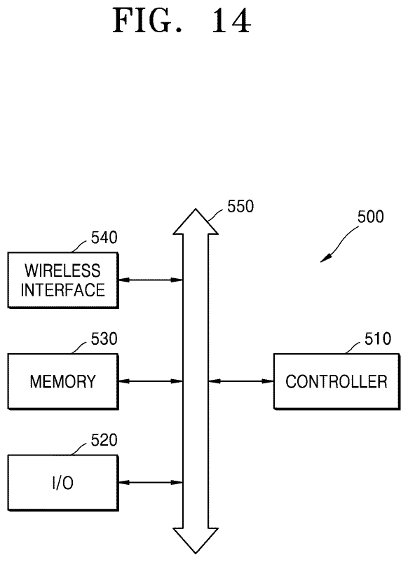

FIG. 14 is a block diagram of an electronic system including a semiconductor device according to another embodiment.

Referring to FIG. 14, an electronic system 500 may configure a wireless communication device, or a device capable of transmitting and/or receiving information under a wireless environment. The electronic system 5500 includes a controller 510, an input/output device (I/O) 520, a memory 530, and a wireless interface 540, each of which is interconnected through a bus 550.

The controller 510 may include at least one of a microprocessor, a digital signal processor, or a processing device similar thereto. The input/output device 520 may include at least one of a keypad, a keyboard, and a display. The memory 530 may be used to store instructions or commands executed by the controller 510. For example, the memory 530 may be used to store user data. The electronic system 500 may use the wireless interface 540 to transmit/receive data through a wireless communication network. The wireless interface 540 may include an antenna and/or a wireless transceiver. In some embodiments, the electronic system 500 may be used in communication interface protocols of third-generation communication systems, such as code division multiple access (CDMA), global system for mobile communications (GSM), north American digital cellular (NADC), extended-time division multiple access (E-TDMA), and/or wide band code division multiple access (WCDMA). The electronic system 500 may include the semiconductor devices 100, 101, 102, and 103 according to the embodiments described with reference to FIGS. 1 to 4 or the memory device 200 according to the embodiment described with reference to FIGS. 9 to 11.

According to the semiconductor device of the present disclosure, the ferroelectric layer includes a crystalline material and may increase and/or maximize polarization by including the first layer, the second layer, and the third layer sequentially stacked, and may increase the memory window of the semiconductor device by reducing the capacitance of the ferroelectric layer.

According to the present disclosure, a semiconductor device and a memory device in which a dispersion of electrical characteristics is improved and a memory window is increased are provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel layer;
a ferroelectric layer on the channel layer; and
a gate electrode on the ferroelectric layer, wherein
the ferroelectric layer includes a crystalline material,
the ferroelectric layer includes a first layer including zirconium oxide, a second layer including hafnium oxide, and a third layer including hafnium zirconium oxide, and
the first layer, the second layer, and the third layer are sequentially stacked.

2. The semiconductor device of claim 1, wherein a crystalline direction of the first layer, a crystalline direction of the second layer, and a crystalline direction of the third layer are aligned in a same direction.

3. The semiconductor device of claim 2, wherein a crystalline direction of the ferroelectric layer is aligned in a direction (001).

4. The semiconductor device of claim 3, wherein, in an in-plane X-ray diffraction (XRD) analysis, the ferroelectric layer has peaks at 6±1° and 12±1°.

5. The semiconductor device of claim 1, wherein the ferroelectric layer comprises a plurality of crystalline phases and an amorphous phase between the plurality of crystalline phases.

6. The semiconductor device of claim 5, wherein the ferroelectric layer comprises the plurality of crystalline phases and the amorphous phase in a volume ratio (vol %) of 20:80 to 80:20.

7. The semiconductor device of claim 5, wherein
the amorphous phase comprises a first amorphous layer including zirconium oxide, a second amorphous layer including hafnium oxide, and a third amorphous layer including hafnium zirconium oxide.

8. The semiconductor device of claim 5, wherein the amorphous phase comprises a low-k dielectric material.

9. The semiconductor device of claim 1, further comprising:
a first interfacial layer on the channel layer.

10. The semiconductor device of claim 1, further comprising:
a second interface layer between the ferroelectric layer and the gate electrode.

11. The semiconductor device of claim 10, further comprising:
a charge trap layer on the ferroelectric layer.

12. The semiconductor device of claim 1, wherein a thickness of the first layer is in a range of 5 Å to 20 Å.

13. The semiconductor device of claim 12, wherein
a thickness of the third layer is larger than a thickness of the second layer, and
the thickness of the third layer is larger than a thickness of the first layer.

14. The semiconductor device of claim 12, wherein the thickness of the first layer is greater than a thickness of the second layer.

15. The semiconductor device of claim 1, wherein a thickness of the second layer is greater than 0 Å and less than or equal to 15 Å.

16. The semiconductor device of claim 1, wherein a thickness of the third layer is in a range of 20 Å to 100 Å.

17. The semiconductor device of claim 1, further comprising:
a low-k material layer, wherein
the ferroelectric layer includes a first ferroelectric layer and a second ferroelectric layer spaced apart from the first ferroelectric layer,
the low-k material layer includes a material having a dielectric constant less than a dielectric constant of the first ferroelectric layer and a dielectric constant of the second ferroelectric layer,
the low-k material layer is between the first ferroelectric layer and the second ferroelectric layer,
the first ferroelectric layer and the second ferroelectric layer each include the first layer including zirconium oxide, the second layer including hafnium oxide, and the third layer including hafnium zirconium oxide, and
in each of the first ferroelectric layer and the second ferroelectric layer, respectively, the first layer, the second layer, and the third layer are sequentially stacked on the channel layer.

18. A memory device comprising
a plurality of memory cells spaced apart from each other vertically on a substrate, wherein
each of the plurality of memory cells comprises a gate electrode extending vertically on the substrate, a plurality of ferroelectric layers spaced apart from each other on the gate electrode, and a channel layer on the plurality of ferroelectric layers,
the plurality of ferroelectric layers include a crystalline material,
the plurality of ferroelectric layers each include a first layer including zirconium oxide, a second layer including hafnium oxide, and a third layer including hafnium zirconium oxide,
the first layer, the second layer, and the third layer are sequentially stacked on the channel layer.

19. A method of manufacturing a semiconductor device, the method comprising:
forming a channel layer;
forming a first precursor layer including zirconium oxide on the channel layer;
forming a second precursor layer including hafnium oxide on the first precursor layer;
annealing at least one of the first precursor layer and the second precursor layer;
forming a third precursor layer including hafnium zirconium oxide on the second precursor layer after the annealing at least one of the first precursor layer and the second precursor layer;
annealing the third precursor layer; and
forming a gate electrode on the third precursor layer.

20. The method of claim 19, further comprising:
forming an etched region by selectively etching an uncrystallized portion of the first precursor layer, an uncrystallized portion of the second precursor layer, and an uncrystallized portion of the third precursor layer; and
forming a low dielectric constant material layer in the etched region, wherein
the etched region is an opening extending through a stack of a remaining portion of the first precursor layer, a remaining portion of the second precursor layer, and a remaining portion of the third precursor layer after the forming the etched region is performed.
